(19) United States
(12) Patent Application Publication
(10) Pub. No.: US 2025/0218949 A1
(43) Pub. Date: Jul. 3, 2025

(54) TECHNIQUES TO FORM INTEGRATED CIRCUIT STRUCTURES WITH CONDUCTIVE INTERCONNECTS

(71) Applicant: Intel Corporation, Santa Clara, CA (US)

(72) Inventors: Sriharsha Karumuri, Hillsboro, OR (US); Dimitri Robert Kioussis, San Jose, CA (US); Sayantika Mukherjee, Forest Grove, OR (US); Md Rakib Uddin, Portland, OR (US); Nathan Strutt, Beaverton, OR (US); Moumita Dutta, Hillsboro, OR (US)

(73) Assignee: Intel Corporation, Santa Clara, CA (US)

(21) Appl. No.: 18/400,313

(22) Filed: Dec. 29, 2023

(51) Int. Cl. H01L 23/532; H01L 21/311; H01L 21/768; H01L 23/522; H01L 23/528

(52) U.S. Cl. CPC H01L 23/53295; H01L 21/76802; H01L 23/5226; H01L 23/5283; H01L 21/31122; H01L 21/76843

(57) ABSTRACT

A fabrication method and associated integrated circuit (IC) structures and devices that include conductive interconnects are described. In one example, techniques for forming conductive interconnects include use of a barrier layer (e.g., in a damascene process) and hard mask removal techniques using a dry etch process with fluorine radicals, which may improve the resistive-capacitive (RC) delay performance in resulting IC structures. In one example, an IC structure includes a first layer including a device contact structure and a second layer over the first layer. In one such example, the second layer includes a conductive interconnect coupled with the device contact structure, and one or more insulator materials surrounding the conductive interconnect, where the one or more insulator materials include fluorine at sidewalls of the conductive interconnect.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1B provide cross-sectional views of IC structures with an interconnect layer including a barrier layer and a conductive interconnect with fluorinated sidewalls.

FIGS. 2A-2B provide cross-sectional views of IC structures with an interconnect layer including a barrier layer and conductive interconnects with fluorinated sidewalls.

FIG. 3 is a flow diagram of an example method for fabricating an IC structure with conductive interconnects, including hard mask removal techniques and use of a barrier layer in an interconnect layer, in accordance with some embodiments.

FIGS. 4A-4G provide cross-sectional side views at various stages in the fabrication of an example IC structure according to the method of FIG. 3, in accordance with some embodiments.

FIG. 5 is a top view of a wafer and dies that may include any of the IC devices disclosed herein, in accordance with any of the embodiments disclosed herein.

FIG. 6 is a side, cross-sectional view of an IC package that may include any of the IC devices disclosed herein, in accordance with various embodiments.

FIG. 7 is a side, cross-sectional view of an IC device assembly that may include any of the IC devices disclosed herein, in accordance with any of the embodiments disclosed herein.

FIG. 8 is a block diagram of an example electrical device that may include any of the IC devices disclosed herein, in accordance with any of the embodiments disclosed herein.

### DETAILED DESCRIPTION

Disclosed herein are techniques for forming IC structures with conductive interconnects and associated IC structures. In one example, techniques for forming conductive interconnects include use of a barrier layer (e.g., in a damascene process) and hard mask removal techniques using a dry etch process with fluorine radicals, which may improve the resistive-capacitive (RC) delay performance in resulting IC structures. The use of fluorine radicals in a hard mask removal process can increase damage (e.g., plasma-induced damage) to exposed surfaces. However, conversion of the surfaces with plasma-induced damage (such as sidewalls of a conductive interconnect) into fluorinated silicon oxide or fluorosilicate glass (FSG) can improve the overall device speed and RC performance. In one example, a resulting IC structure includes an interconnect layer with a barrier layer and a conductive interconnect, where sidewalls of the conductive interconnect and/or the barrier layer include fluorinated silicon oxide or FSG. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

For the past several decades, the scaling of features in IC structures has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize every portion of IC structures becomes increasingly significant. For example, the techniques used to pattern metal layers to form conductive interconnects in an IC structure can impact device performance.

A damascene process is commonly used to form metal layers in an IC structure. A damascene process is an additive transfer process in which metal is deposited over a patterned mask. In some examples, a hard mask, such as a metal hard mask is used in a damascene process. For example, a lithography pattern is transferred on to the metal hard mask and then onto an underlying interlayer dielectric (ILD) using subsequent etches. Post ILD-etch, the damascene pattern is formed in the ILD with the metal hard mask over the ILD. Post-damascene patterning, metal hard masks may be removed by a wet isotropic etch process. In one such example, to remove a hard mask with non-selective metal hard mask chemistries, a carbon-based fill material is first provided to protect the metal in the trench or via opening. Subsequently, the carbon-based fill material is recessed to expose the hard mask, and the hard mask is removed with wet chemistries. Finally, the carbon-based fill material may be removed with an ashing process. The carbon-based fill material can therefore protect underlying metal features from the etch process, however, the technique can negatively impact the dielectric constant of the interlayer dielectric (ILD) material in which the opening is formed, which can deteriorate the RC delay performance of the conductive interconnects.

Another technique for removing metal hard masks post-damascene patterning is to use a wet etch chemistry that is selective to the underlying metal. However, using a selective wet etch chemistry to remove the metal hard mask limits the choice of metal for the underlying metal features as well as the choice of material for the metal hard mask. For example, relying on a selective wet etch chemistry to remove the metal hard mask can limit the material choices to metals with relatively high resistance (e.g., high via kelvin resistance and/or high resistance in the underlying metal features). Additionally, using a wet etch chemistry may result in moisture in-take into the ILD. Another technique for removing metal hard masks is using chemical mechanical polishing (CMP). However, using CMP to remove the hard mask can result in metallization problems. For example, using CMP to remove the hard mask may result in some of the metal hard mask remaining, resulting in an increased stack height (e.g., e.g., increased height of the stack including remaining metal hard mask material and the ILD under the hard mask, etc.). An increased stack height can result in improper metallization and/or missing metal fill defects.

In contrast, hard mask-removal techniques including a fluorine-radical based etch process and use of a barrier layer over the ILD in the final stack can enable not only effective removal of a hard mask post-damascene etch, but may also enable an improvement in the RC delay performance of the interconnect layer. In one example, a barrier layer is provided over the ILD prior to patterning. After patterning (e.g., after forming an opening in the ILD for a via or metal line), a fluorine-radical based removal chemistry is employed to etch the metal hard mask selective to the metal in the opening. Using a fluorine-based etch process can simplify the etch process (e.g., eliminating the need for deposition and removal of the carbon-based fill material) to remove the hard mask without increasing the dielectric constant of the ILD. On the contrary, the fluorine-based etch process can cause fluorination of sidewalls of the opening and the barrier layer, which can reduce the dielectric constant of the interconnect layer. However, fluorine reactants or radicals may cause the ILD to become hydrophilic. Exposing a hydrophilic ILD to a slurry and rinse (e.g., during a CMP process) can result in moisture uptake. Moisture uptake can increase the dielectric constant of the ILD, which can lower RC performance. Typically, a barrier layer is polished off during a CMP process and not present in the final IC structure. In contrast, in one example, the presence of the barrier layer over the ILD in the final IC structure can prevent moisture imbibition into the ILD. Thus, use of a fluorine-radical based etch chemistry to remove a hard mask and use of a barrier layer to form a composite ILD layer (e.g., the ILD with the barrier layer) can enable improved RC performance of the interconnect layer.

IC structures as described herein, in particular IC structures with an interconnect layer including a barrier layer and a conductive interconnect with fluorinated sidewalls, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of a radio frequency (RF) receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of the presence of IC structures with an interconnect layer including a barrier layer and a conductive interconnect with fluorinated sidewalls.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

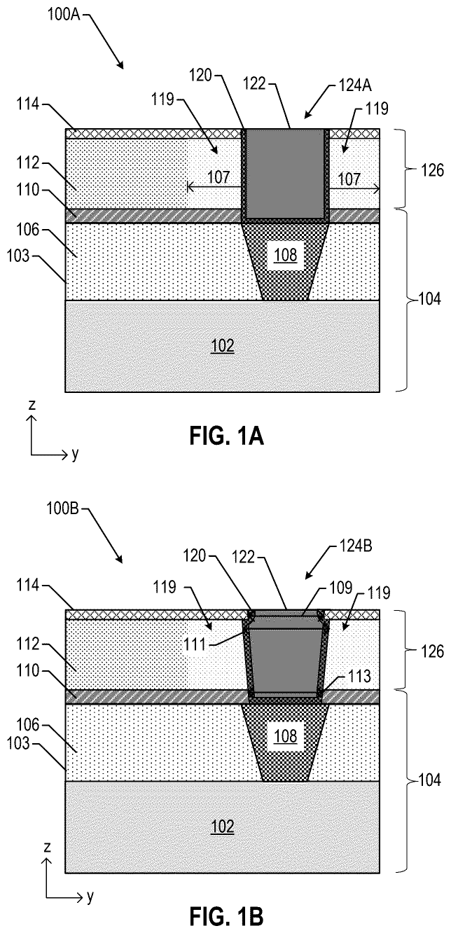

FIGS. 1A-1B provide cross-sectional views of IC structures with an interconnect layer including a barrier layer and a conductive interconnect with fluorinated sidewalls. FIG. 1A illustrates an IC structure 100A that includes a device region 104 and an interconnect layer 126 over the device region 104. The device region 104 may include device components such as transistors, memory cells, resistors, capacitors, and/or other devices. In one example, the IC structure 100A includes transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors. The device region 104 may be referred to as “front-end-of line (FEOL) layer(s)” of the IC structure 100A. In the illustrated example, the device region 104 includes a layer 103, which includes a conductive contact structure 108 that is coupled with another device element (not shown in FIG. 1A) in the layer 102. In one such example, the contact structure 108 may be coupled with a gate, source region, or drain region of a transistor in the layer 102.

In one example, the contact structure 108 includes an electrically conductive fill material within side walls of the contact structure 108, which may include tungsten and/or another metal. Although not shown, sidewalls of the contact structure may include one or more liners, where the liners may include, but not limited to, materials comprising silicon and nitrogen (e.g., silicon nitride), materials comprising silicon and oxygen (e.g., silicon oxide), materials comprising silicon and carbon (e.g., silicon carbide), and/or their composites. The insulator material 106 surrounding the conductive contact structure 108 may include a suitable dielectric material (e.g., a suitable ILD). In some examples, the insulator material 406 may be a low-k dielectric material. Some examples of low-k dielectric materials include, but are not limited to, a material including silicon, oxygen, carbon, and hydrogen or a material including silicon, oxygen, and a methyl group (e.g., SiCOH), silicon dioxide, carbon-doped oxide, silicon nitride, organic polymers such as perfluorocyclobutane or polytetrafluoroethylene, fused silica glass (FSG), and organosilicates such as silsesquioxane, siloxane, organosilicate glass, or another low-k dielectric material. The IC structure 100A also includes an etch stop layer 110 over the insulator material 106. In one example, the etch stop layer 110 includes a material (e.g., an insulator material) that is etch-selective with respect to insulator material 112 and the insulator material of the barrier layer 114 over the etch stop layer 110.

The IC structure 100A also includes an interconnect layer 126 over the device region 104. The interconnect layer includes a conductive interconnect 124A and one or more insulator materials surrounding the conductive interconnect 124A. The conductive interconnect includes a conductive fill material 122 (e.g., a metal such as copper or another suitable conductive material). The example illustrated in FIG. 1A also includes a conductive liner 120. In other examples, a liner may be absent, or additional liners may be present. In the example illustrated in FIG. 1A, the one or more insulators surrounding the conductive interconnect 124A include an insulator material 112 and a barrier layer 114 over the insulator material 112, where the barrier layer includes an insulator material with at least one material property that is different from the insulator material 112. In one example, the insulator material of the barrier layer 114 has one or more of: a different material composition, a higher density, and a higher dielectric constant than the insulator material 112.

In one example, the insulator material 112 may be any suitable dielectric material, such as those described above. The insulator material 112 may be the same as or different from the insulator material 106 surrounding the conductive contact structure 108. In one example, the barrier layer 114 includes silicon oxide. The barrier layer 114 may act as a hermetic barrier to prevent moisture uptake and/or damage in the insulator material 112. In some examples, the barrier layer 114 may be referred to as a hermetic layer, a hermetic seal or cap, a dielectric layer or cap, or a silicon oxide layer or cap (e.g., in an example in which the barrier layer includes silicon oxide).

In one example, the barrier layer 114 has a smaller thickness than the insulator material 112, where the thickness of the barrier layer 114 and the insulator material 112 are dimensions in a plane substantially orthogonal to the layer 102 (e.g., a dimension along the z-axis as shown in FIG. 1A). In one example the thickness of the barrier layer 114 is in a range of about 3-20 nanometers, about 4-10 nanometers, or about 5-8 nanometers. In one such example, the presence of the barrier layer 114 having a thickness of at least about 4-5 nanometers in the final IC structure can improve RC performance. Other barrier layer thicknesses are also possible. In one example, the barrier layer 114 is absent from the IC structure 100A, however, the presence of the barrier layer 114 can lower the overall dielectric constant of the interconnect layer 126, which can enable a reduction in RC delay.

In one example, the barrier layer 114 and sidewalls 119 of the conductive interconnect 124A include fluorine. In one such example, the barrier layer 114 and the sidewalls 119 became fluorinated during an etch process to remove a hard mask after forming an opening for the conductive interconnect 124A. In one example, the depth and concentration of fluorine in the sidewalls 119 and in the barrier layer 114 may depend upon a number of parameters, such as the etch chemistry, etch time, temperature, etc. In one example, fluorine is present in the barrier layer 114 and in the sidewalls 119 of the insulator material 112 at concentrations that are greater than impurity levels (e.g., greater than about 10¹³ atoms per cubic centimeter (cm⁻³) or greater than about 10¹⁵ atoms per cubic centimeter (cm⁻³)). In one example, the concentration of fluorine in the barrier layer 114 and/or in the sidewalls 119 is in a range of about 1-6% or in a range of about 2-5%. Other concentrations of fluorine are also possible (e.g., less than 1% but still at a sufficient concentration to improve the RC performance of the interconnect layer, or greater than 6%). In one example, fluorine is present in the entire thickness of the barrier layer 114. In one such example, fluorine may be present at about the same concentration in the entire thickness of the barrier layer 114. In other examples, fluorine may be present at higher concentrations in a volume furthest from the insulator material 112 and at the sidewalls 119, and may be present at lower concentrations or absent in a volume of the barrier layer 114 closest to the insulator material 112. In one example, the fluorine may be present in the sidewalls 119 of the conductive interconnect 124A (e.g., in the insulator material 112 at the sidewalls 119 of the conductive interconnect 124A) to a depth 107 in a range of about 5-30 nanometers or about 20-25 nanometers, where the depth is a dimension in a plane substantially parallel to the layer 102 (e.g., along the y-axis as shown in FIG. 1A).

Thus, the IC structure 100A of FIG. 1A includes a first layer 103 including a first conductive element (e.g., the conductive contact structure 108), a second layer 126 over the first layer 103, the second layer 126 including a first insulator material 112 (e.g., a low-k ILD), a second insulator material (e.g., the insulator material of the barrier layer 114) over the first insulator material 112, where the second insulator material is different from the first insulator material 112, and where the second insulator material includes fluorine. The IC structure 100A includes a second conductive element (e.g., the conductive interconnect 124A) connected to the first conductive element (e.g., the conductive contact structure 108) through the first insulator material and the second insulator material, where sidewalls 119 of the second conductive element include fluorine. In one example, the presence of the fluorine in the sidewalls 119 of the conductive interconnect and in the barrier layer 114 can result in a lower dielectric constant of the interconnect layer 126 (e.g., of a composite ILD including the insulator material 112 and the barrier layer 114) and improved RC delay.

FIG. 1B illustrates another IC structure 100B that includes an interconnect layer 126 with a barrier layer 114 and a conductive interconnect 124B with fluorinated sidewalls 119. In the example illustrated in FIG. 1B, the conductive interconnect 124B has a narrower top portion in the same plane as the barrier layer 114 than a portion in the same plane as the insulator material 112. In one such example, an etch process used to form an opening for the conductive interconnect 124B results in narrower sidewalls where the barrier layer 114 is etched, e.g., due to the insulator material of the barrier layer 114 having a higher density than the insulator material 112. In one such example, the etch process may form an undercut portion below the barrier layer, where more of the insulator material 112 is removed than the material of the barrier layer. In the example illustrated in FIG. 1B, the conductive interconnect has a first width 109 in a same plane as the barrier layer 114, and a second width 111 in a same plane as the insulator material 112, where the first width 109 is smaller than the second width, and where the first width and second width are dimensions of the conductive interconnect 124B in planes substantially parallel to the layers 103 or 102. In one example, the conductive interconnect may also have a tapered shape. For example, the conductive interconnect 124B has a third width 113 in a third plane with the insulator material 112 at a portion of the conductive interconnect opposite the top portion by the barrier layer 114 (e.g., where the third plane is closer to the layer 103 than the second plane), where the third width 113 is smaller than the second width 111. In one such example, the first width 109 may be smaller than, about the same as, or larger than the third width 113. Thus, in addition to fluorinated sidewalls and a fluorinated barrier layer, an IC structure formed using a fluorine-based etch process to remove a hard mask as discussed herein may have an interconnect structure with a narrower width in the same layer as the barrier layer 114.

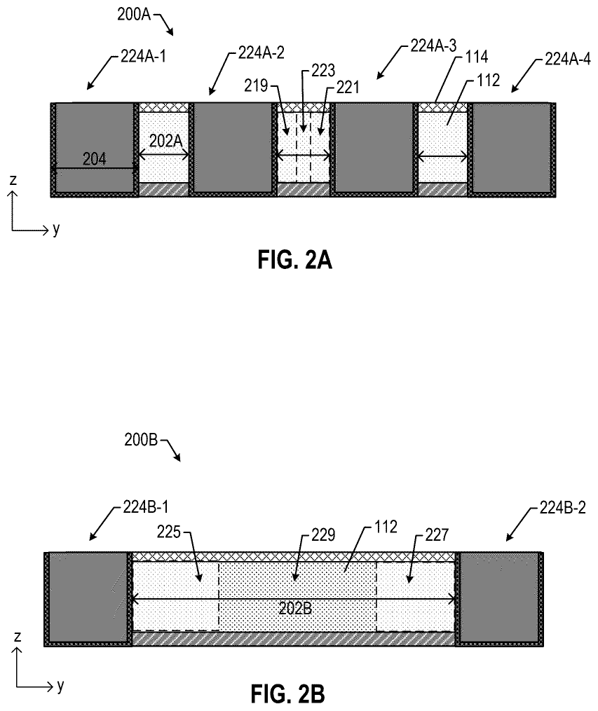

FIGS. 2A-2B provide cross-sectional views of IC structures with an interconnect layer including a barrier layer and multiple conductive interconnects with fluorinated sidewalls. FIG. 2A illustrates an example of an IC structure 200A with conductive interconnects 224A-1-224A-4 with a narrower pitch, and FIG. 2B illustrates an example of an IC structure 200B with conductive interconnects 224B-1-224B-2 with a wider pitch. The conductive interconnects 224A-1-224A-4 and 224B-1-224B-2 may be examples of the conductive interconnects 124A and 124B of FIGS. 1A-1B, discussed above.

Turning first to FIG. 2A, the IC structure 200A includes conductive interconnects 224A-1-224A-4, where adjacent pairs of the conductive interconnects 224A-1-224A-4 are separated by a distance 202A. Note that although each pair of adjacent conductive interconnects 224A-1-224A-4 are shown as separated by about the same distance 202A, different pairs of adjacent conductive interconnects in an IC structure may be separated by the same or a different distance. In one example, the distance 202A between adjacent conductive interconnects 224A-1-224A-4 is less than a width 204 of one of the conductive interconnects 224A-1-224A-4, where the width 204 of a conductive interconnect and the distance 202A are dimensions in a plane substantially parallel to an underlying layer (e.g., a support or other layer, such as the layer 103 of FIGS. 1A-1B). In one example, the distance 202A between adjacent conductive interconnects 224A-1-224A-4 is in a range of 10-25 nanometers, or 15-20 nanometers. Other pitches are also possible.

In one example, fluorine is present in the entire continuous volume of the insulator material 112 between adjacent conductive interconnects 224A-1-224A-4 (e.g., fluorine is present in at a concentration greater than impurity levels). In the example illustrated in FIG. 2A, the insulator material between the conductive interconnect 224A-2 and the conductive interconnect 224A-2 includes a first volume 219 in contact with the conductive interconnect 224A-2, a second volume 221 in contact with the conductive interconnect 224A-2, and a third volume 223 between and in contact with the first volume 219 and the second volume 221. In one such example, fluorine is present in the first volume 219, the second volume 221, and the third volume 223. In one example, a concentration of fluorine is about the same in the first volume 219, the second volume 221, and the third volume 223. Thus, in the example illustrated in FIG. 2A with narrower pitch interconnects, the sidewalls of adjacent conductive interconnects 224A-1-224A-4 include fluorine up to a depth such that fluorine is present in the entire volume between adjacent conductive interconnects.

Turning to FIG. 2B, the IC structure 200B includes conductive interconnects 224B-1-224B-2, where adjacent pairs of the conductive interconnects 224B-1, 224B-2 are separated by a distance 202B. In one example, the distance 202B between adjacent conductive interconnects 224B-1, 224B-2 is less than a width 204 of one of the conductive interconnects 224B-1, 224B-2, where the width 204 of a conductive interconnect and the distance 202B are dimensions in a plane substantially parallel to an underlying layer (e.g., a support or other layer, such as the layer 103 of FIGS. 1A-1B). In one example, the distance 202B between adjacent conductive interconnects 224B-1, 224B-2 is in a range of 25-60 nanometers, 35-55 nanometers, or 40-50 nanometers. Other pitches are also possible.

Unlike the example in FIG. 2A where the entire volume of insulator material between adjacent conductive interconnects includes fluorine, FIG. 2B illustrates an example in which fluorine is absent (or present at significantly lower concentrations) in a mid-volume between sidewalls of adjacent conductive interconnects. For example, the insulator material 112 between the conductive interconnects 224B-1 and 224B-2 has a first volume 225 in contact with the conductive interconnect 224B-1, a second volume 227 in contact with the conductive interconnect 224B-2, and a third volume 229 between the first volume 225 and the second volume 227, where a concentration of fluorine is lower or absent in the third volume 229 than in the first volume 225 and the second volume 227. In one example, in addition to different concentrations of fluorine in volumes 225, 227 of the insulator material 112 proximate to the conductive interconnects, other elemental differences between the third volume 229 and the first and second volumes 225, 227 may be seen as a result of the fluorine-based etch process used to remove a hard mask after interconnect patterning. For example, a mid-volume (e.g., the third volume 229) between adjacent conductive interconnects 224B-1, 224B-2 may have a greater concentration of carbon than volumes 225, 227 that are closer to the conductive interconnects 224B-1, 224B-2. In one example, the volumes 225, 227 that are closer to the conductive interconnects 224B-1, 224B-2 may have a higher concentration of oxygen than the volume 229 between the volumes 225, 227. Such differences may be the result of the etch process in which carbon may be removed at the sidewalls of the conductive interconnects 224B-1, 224B-2, leaving behind oxide. Thus, the examples of FIGS. 2A-2B illustrate that fluorine may be present at different concentrations in the insulator material between adjacent conductive interconnects depending on the pitch of the conductive interconnects. In some examples (e.g., such as the example in FIG. 2A), fluorine may be present in an entire volume between adjacent conductive interconnects. In other examples (e.g., such as the example in FIG. 2B), fluorine may be present at the sidewalls of conductive interconnects, but there may be a volume between adjacent conductive interconnects in which fluorine is absent.

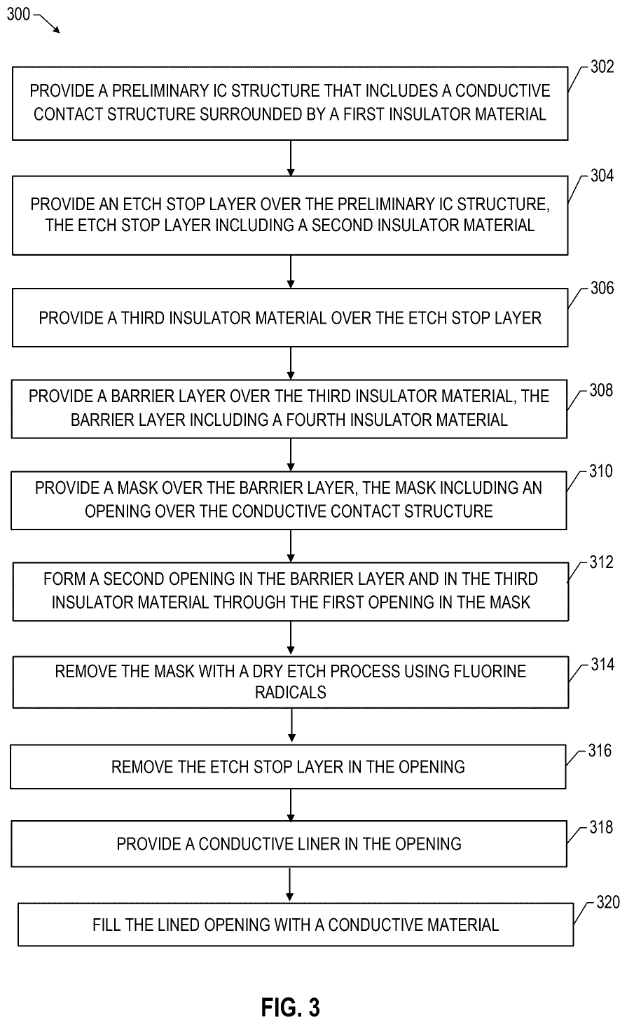

FIG. 3 is a flow diagram of an example method for fabricating an IC structure with conductive interconnects, including hard mask removal techniques and use of a barrier layer in an interconnect layer, in accordance with some embodiments. Although the operations of the method of FIG. 3 are illustrated once each and in a particular order, the operations may be performed in any suitable order and repeated as desired. For example, one or more operations may be performed in parallel to fabricate multiple IC structures with an interconnect layer including a barrier layer and a conductive interconnect with fluorinated sidewalls substantially simultaneously. In another example, the operations may be performed in a different order to reflect the structure of an IC device in which an interconnect layer including a barrier layer and a conductive interconnect with fluorinated sidewalls will be implemented.

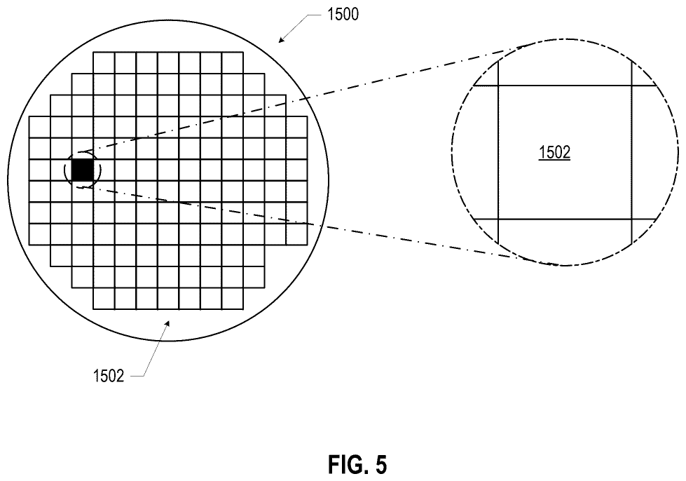

In addition, the example fabricating method of FIG. 3 may include other operations not specifically shown in FIG. 3, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 5 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

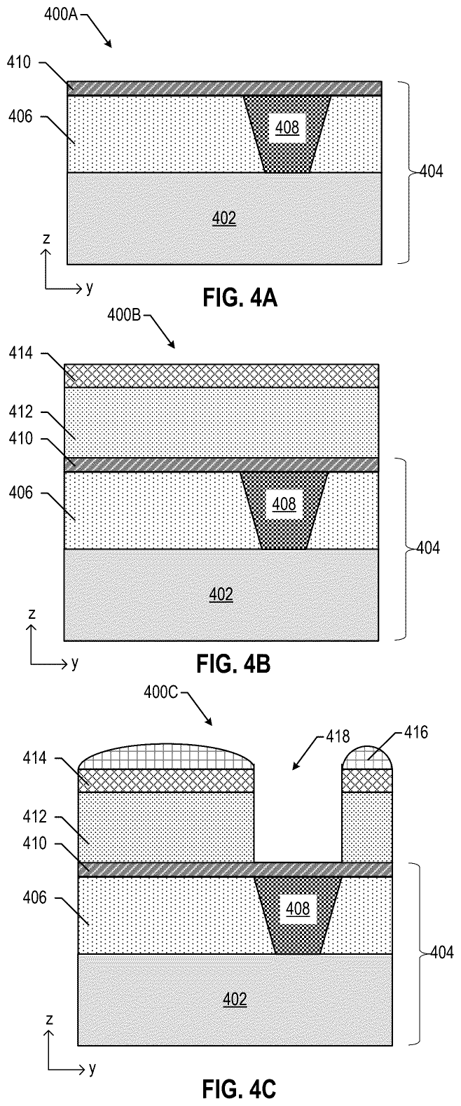

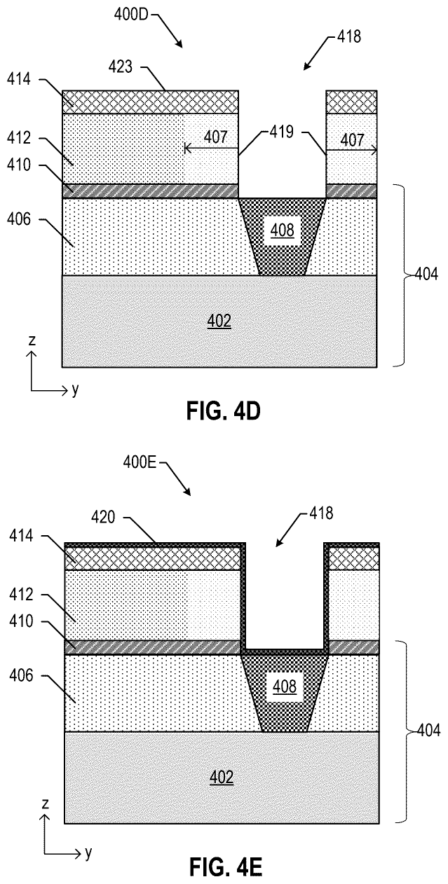

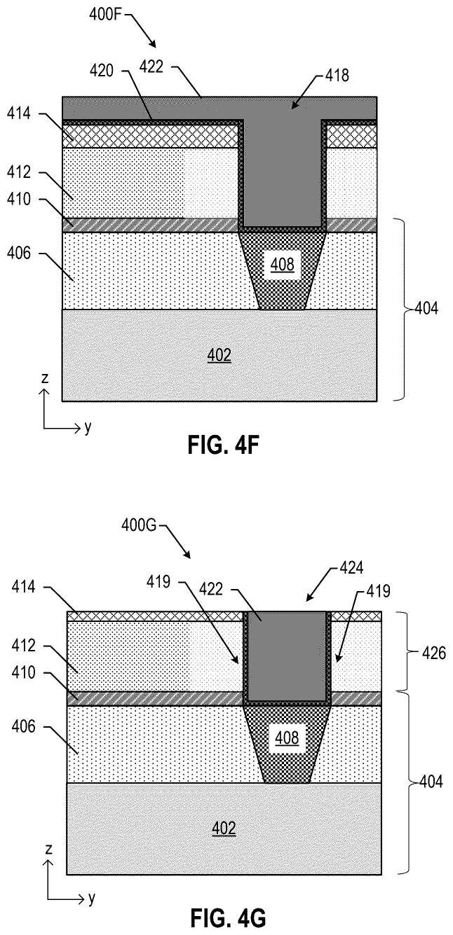

FIGS. 4A-4G provide cross-sectional side views at various stages in the fabrication of an example IC structure according to the method of FIG. 3, in accordance with some embodiments.

Turning to FIG. 3, the method 300 begins with a process 302 of providing a preliminary IC structure that includes a conductive contact structure surrounded by a first insulator material and a process 304 of providing an etch stop layer over the preliminary IC structure, where the etch stop layer includes a second insulator material. An IC structure 400A of FIG. 4A illustrates an example result of the processes 302 and 304. As can be seen in FIG. 4A, the IC structure includes a conductive contact structure 408 surrounded by an insulator material 406. The conductive contact structure can be, for example, a contact structure connected with a device component in a layer 402, and therefore may be referred to as a device contact structure or a device contact. For example, the layer 402 may include device components such as transistors, memory cells, resistors, capacitors, and/or other devices. In one such example, the contact structure 408 may be coupled with a gate, source region, or drain region of a transistor in the layer 402. Thus, the IC structure 400A may include a device region 404 that includes a layer 402 with devices and may also include a layer with the contact structure 408. The device region 404 may be referred to as “front-end-of line (FEOL) layer(s)” of the IC structure 400A.

In one example, the contact structure 408 includes an electrically conductive fill material within side walls of the contact structure 408, which may include tungsten and/or another metal. Although not shown, sidewalls of the contact structure may include one or more liners, where the liners may include, but not limited to, materials comprising silicon and nitrogen (e.g., silicon nitride), materials comprising silicon and oxygen (e.g., silicon oxide), materials comprising silicon and carbon (e.g., silicon carbide), and/or their composites. The insulator material 406 surrounding the conductive contact structure 408 may include a suitable dielectric material, such as those described above. The IC structure also includes an etch stop layer 410 over the layer with the conductive contact structure 408. In one example, the etch stop layer 410 includes a material (e.g., an insulator material) that is etch-selective with respect to one or more materials that are to be provided over the etch stop layer in a subsequent process. In one example, the etch stop layer 410 includes a suitable ILD such as those discussed above.

One or more interconnect layers, which may include metal interconnects and insulator layers, may be formed over the device region 404 to form connections between device components and other device components, ground, or power. Interconnect layers may also be referred to as BEOL layer(s). For example, referring again to FIG. 3, the method 300 continues with a process 306 of providing a third insulator material over the etch stop layer and a process 308 of providing a barrier layer over the third insulator material, where the barrier layer includes a fourth insulator material. An IC structure 400B of FIG. 4B illustrates an example result of the processes 306 and 308. As can be seen in FIG. 4B, the IC structure 400B includes an insulator material 412 over the etch stop layer and a barrier layer 414 over the insulator material 412. In one example, the insulator material 412 may be any suitable dielectric material, such as those described above. The insulator material 412 may be the same as or different from the insulator material 406 surrounding the conductive contact structure 408.

The barrier layer 414 includes an insulator material that has at least one material property that is different from the insulator material 412. In one example, the insulator material of the barrier layer 414 has one or more of a higher density and a higher dielectric constant than the insulator material 412. In one example, the barrier layer 414 includes silicon oxide. The barrier layer 414 may act as a hermetic barrier to prevent moisture uptake and/or damage in the insulator material 412 under the barrier layer 414 in subsequent processes. In some examples, the barrier layer may be referred to as a hermetic layer, a hermetic seal or cap, a dielectric layer or cap, or a silicon oxide layer or cap (e.g., in an example in which the barrier layer includes silicon oxide). In one example, the insulator material 406 includes a low-k dielectric including silicon, oxygen, carbon, and hydrogen, the barrier layer includes silicon oxide, and the etch stop layer 410 includes an insulator material that is etch-selective with respect to the insulator material 412 and the barrier layer 414, such as aluminum oxide or another suitable etch stop material.

Referring again to FIG. 3, the method 300 continues with a process 310 of providing a mask over the barrier layer and a process 312 of forming an opening in the barrier layer and in the third insulator material through an opening in the mask. An IC structure 400C of FIG. 4C illustrates an example result of the processes 310 and 312. As can be seen in FIG. 4C, a mask 416 is provided over the barrier layer 414, which had an opening over the conductive contact structure 408. An opening 418 has been formed in the barrier layer 414 and in the insulator material 412 over the conductive contact structure 408 through the opening in the mask 416. In one example, forming the opening 418 is a part of a damascene process to form a conductive interconnect over the conductive contact structure 408. The damascene process may be a single or dual damascene process, and may involve a via first or via last technique. In one example, the mask 416 is or includes a metal/metallic hard mask. The mask 416 may include any suitable hard mask material such as a metal nitride, a metal oxide, a metal carbide, or other suitable mask material. For example, the mask 416 may include titanium nitride, titanium oxide, or another suitable hard mask material. The insulator material 412 and the barrier layer 414 may then patterned, e.g., with an etch process, that stops on the etch stop layer 410. The opening 418 may be a hole or a trench that can be filled with a metal to form a conductive line (e.g., a conductive trace) or a conductive via.

Referring again to FIG. 3, the method 300 continues with a process 314 of removing the mask with a dry etch process using fluorine radicals and a process 316 of removing the etch stop layer in the opening. An IC structure 400D of FIG. 4D illustrates an example result of the processes 314 and 316. As can be seen in FIG. 4D, the mask 416 has been removed from over the barrier layer 414 of the IC structure 400D. The etch stop layer 410 exposed in the opening 418 has also been removed in the IC structure 400D. In one example, the etch stop layer 410 and the mask 416 may be removed with the same or with different etch processes.

In one example, the mask 416 is removed with a dry isotropic etch using a fluorine radical-based chemistry that is selective to the metal of the conductive contact structure 408 in the opening 418. In one such example, the mask 416 is removed with a mixture of hydrogen and fluorine radicals. For example, removing the mask 416 may involve using a remote plasma to generate fluorine and hydrogen radicals. In one example, a fluorine and hydrogen radical mixture reacts with titanium nitride (TiN) or titanium oxide (TiOx) and forms titanium fluoride (TiFx). Then, titanium fluoride byproduct can be sublimated (e.g., at temperatures greater than 350° C.) In one example, at appropriate ratios of fluorine, hydrogen and/or other precursors, metals such as tungsten and other metals may not be etched or damaged during the mask removal. In addition, corrosion related defects that are commonly seen with wet chemistry can be significantly reduced. Furthermore, using a fluorine-based etch process can enable simplifying the hard mask removal process because the mask 416 can be removed without depositing, recessing, and removing a carbon-based fill material in the opening 418. Use of a fluorine and hydrogen radical chemistry may transform a low-k ILD (e.g., the insulator material 406) into a hydrophilic material. In one example, to minimize uptake of water or other polar groups during subsequent processes such as CMP of copper layer or other wet cleans, the barrier layer 410 can be left (e.g., not removed) over the insulator material 406 during CMP removal of copper.

Using a fluorine-based etch process can result in fluorinating one or more materials of the IC structure 400D. In one example, removing the mask with the fluorine-based dry etch process results in fluorinating sidewalls 419 of the opening 418 as well as the barrier layer 414. Thus, after removing the mask 416, fluorine is present in sidewalls 419 of the opening 418 for a conductive interconnect. In one example, fluorine is also present in the barrier layer 414. In one such example, fluorine is present in the entire thickness of the barrier layer (e.g., from an exposed surface 423 to the insulator material 412, where thickness of the barrier layer is a dimension in a plane substantially perpendicular to the layer 402). In one example, the material at the sidewalls 419 and in the barrier layer 414 is converted to fluorinated SiOx or FSG as a result of the fluorine-based etch process.

In one example, the depth and concentration of fluorine in the sidewalls 419 and in the barrier layer 414 may depend upon a number of parameters, such as the etch chemistry, etch time, temperature, etc. In one example, the fluorine may be present in the sidewalls 419 of the opening 418 to a depth 407 in a range of about 5-30 nanometers or about 20-25 nanometers, where the depth is a dimension in a plane substantially parallel to the layer 402. In other examples, fluorine may be present in the sidewalls 419 to another depth (e.g., greater than 30 nanometers or less than 5 nanometers). As discussed above, depending on the interconnect pitch, the entire volume of insulator material between interconnects may be fluorinated (e.g., fluorine may be present in the entire volume between adjacent interconnects).

Thus, removing the mask 416 using H/F-radicals may cause the barrier layer 414 and the insulator material 412 to become fluorinated. The overall dielectric constant of the fluorinated barrier layer 414 and the fluorinated insulator material 412 can be decreased, which can enable an overall improvement of RC delay performance of the metal layer. In one example, the dielectric constant of a composite ILD that includes the fluorinated insulator material 412 and fluorinated barrier layer 414 may be about 3.5. In one example, the RC performance can be further enhanced by increasing the fluorination of the barrier layer and/or insulator material 412.

Referring again to FIG. 3, the method 300 continues with a process 318 of providing a conductive liner in the opening. An IC structure 400E of FIG. 4E illustrates an example result of the process 318. As can be seen in FIG. 4E, the IC structure 400E includes a conductive liner 420 on a bottom and sidewalls 419 of the opening 418 and on the exposed surface 423 of the barrier layer 414. In one example, the conductive liner 420 includes a metal such as tantalum, cobalt, or another conductive material.

The method 300 continues with a process 320 of filling the lined opening with a conductive material. An IC structure 400F of FIG. 4F illustrates an example result of the process 320. As can be seen in FIG. 4F, the opening 418 with the liner 420 is filled with a conductive material 422. In one example, the conductive material is copper or another suitable electrically conductive material. Excess material may then be removed from over the barrier layer 414, e.g., via a CMP process or other suitable technique. FIG. 4G illustrates an IC structure 400G in which the excess conductive material 422 has been removed. The example in FIG. 4G also illustrates an IC structure 400G in which the thickness of the barrier layer 414 has been reduced (e.g., with CMP or another technique). In one example the thickness of the barrier layer 414 is in a range of 3-20 nanometers, 4-10 nanometers, or 5-8 nanometers, where thickness is measured in a plane substantially perpendicular to the layer 402. Other barrier layer thicknesses are also possible. In one example, the barrier layer 414 can be removed, however, the presence of a sufficiently thick fluorinated barrier layer post-polish can lower the overall dielectric constant of the interconnect layer 426, which can enable a reduction in RC delay.

Thus, the IC structure 400G includes an interconnect layer 426 with a conductive interconnect 424 connected to a conductive contact structure 408 in a layer under the interconnect layer 426 (e.g., in the device region 404). The conductive interconnect may be, for example, a conductive via or a conductive line or trace. One or more additional interconnect layers may be present above the interconnect layer 426. A collection of interconnect layers may be referred to as a “metallization stack” of the IC structure 400G. Interchangeably, the metallization stack may be referred to as the BEOL) layer(s) of the IC structure 400G, while the device region 404 may be referred to as the FEOL layer(s) of the IC structure 400G. Electrical signals, such as power and/or input/output (I/O) signals, may be routed to and/or from the devices (e.g., the transistors) of the device region 404 through one or more interconnect layers disposed on the device region 404 (illustrated in FIG. 4G as an interconnect layer 426). For example, electrically conductive features of the device region 404 (e.g., the electrically conductive material of the transistor contact structures or other conductive elements) may be electrically coupled with the interconnect structures (e.g., the conductive interconnect 424) of the interconnect layer 426. The interconnect structures may be arranged within the interconnect layers of the metallization stack to route electrical signals according to a wide variety of designs. Although a single interconnect layer 426 is depicted in FIG. 4G, embodiments of the present disclosure include IC structures having more interconnect layers than depicted.

In some embodiments, the interconnect structures, such as the conductive interconnect 424) may include conductive lines and/or conductive vias filled with an electrically conductive material such as a metal. The lines may be arranged to route electrical signals in a direction of a plane that is substantially parallel with a surface of the support upon which the device region 404 is formed. For example, the lines may route electrical signals in a direction in and out of the page from the perspective of FIG. 4G. The vias may be arranged to route electrical signals in a direction of a plane that is substantially perpendicular to the surface of the support upon which the device region 404 is formed. In some embodiments, the vias may electrically couple lines of different interconnect layers of the metallization stack together.

Thus, the method 300 of FIG. 3 is an example method for fabricating an IC structure with conductive interconnects, including hard mask removal techniques and use of a barrier layer in an interconnect layer. Using a fluorine radical-based dry etch process to remove a hard mask post-patterning can reduce the number of processes involved in the mask removal, which can minimize the defects related to opens or voids in the metal lines. Using a fluorine-radical based dry etch process to remove the hard mask can also help improve RC performance due to not needing an ashing process to remove a carbon-based fill material from the opening. Performing the method 300 of FIG. 3 may result in features in the final IC structures that are characteristic of the use of the method 300. For example, one such feature is illustrated in the IC structure 400G shown in FIG. 4G, which shows a conductive interconnect 424 with fluorinated sidewalls 419 and a fluorinated barrier layer 414 in the interconnect layer 426. The presence of fluorine in the sidewalls 419 and in the barrier layer 414 can lower the dielectric constant of the fluorinated ILD layers, which can reduce RC delay in the interconnect layer.

IC devices/structures that include an interconnect layer including a barrier layer and a conductive interconnect with fluorinated sidewalls as described herein (e.g., as described with reference to FIGS. 1A-4G) may be used to implement any suitable components. For example, in various embodiments, IC structures described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC devices and structures disclosed herein, e.g., the IC structures 100A, 100B, 200A, 200B, 400G or any variations thereof, may be included in any suitable electronic component.

FIGS. 5-8 illustrate various examples of apparatuses that may include any of the IC devices/structures disclosed herein.

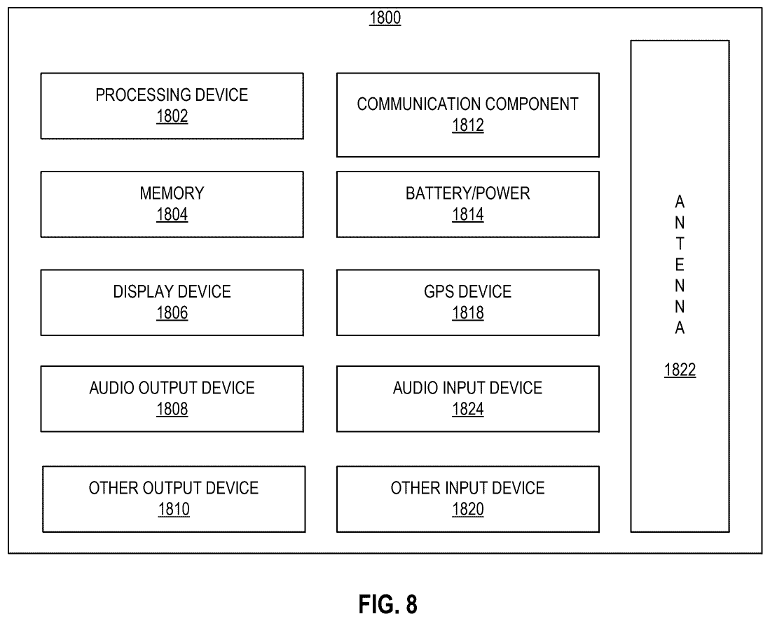

FIG. 5 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC structures 100A, 100B, 200A, 200B, 400G, described herein), one or more transistors (e.g., nanoribbon transistors of the IC structures 100A, 100B, 200A, 200B, 400G) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array.

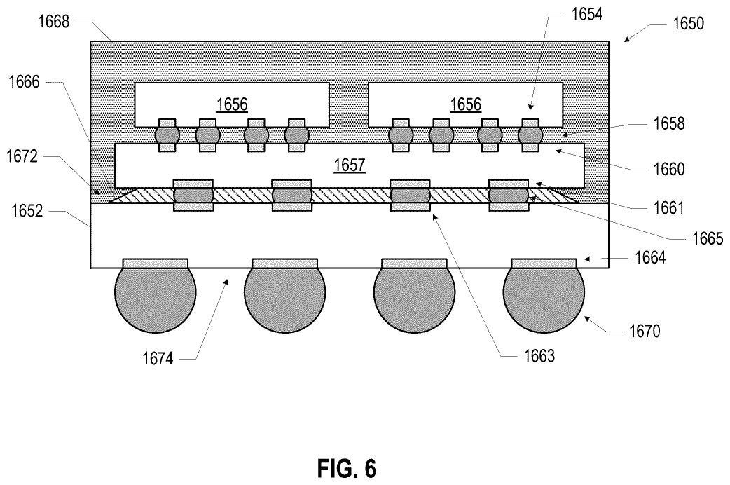

FIG. 6 is a side, cross-sectional view of an example IC package 1650 that may include one or more IC structures in accordance with any of the embodiments disclosed herein (e.g., any of the IC structures 100A, 100B, 200A, 200B, 400G, described herein). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects discussed above with reference to FIG. 5.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 6 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 6 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

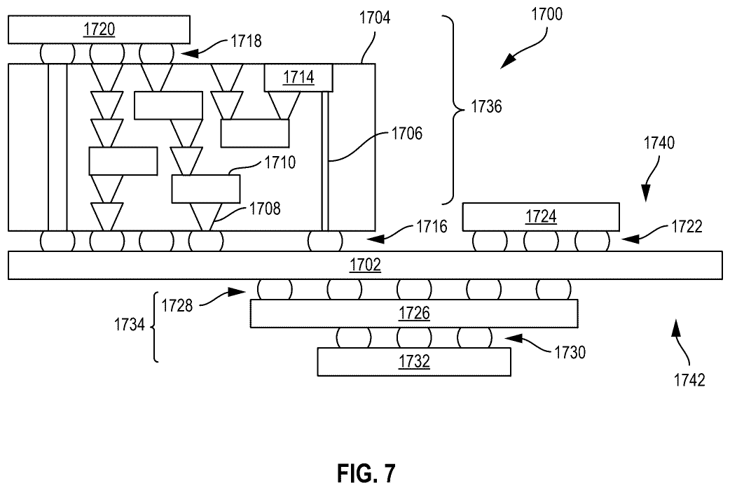

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 6 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 7.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 6 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 6, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 7 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 6 (e.g., may include one or more the IC structures 100A, 100B, 200A, 200B, 400G).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 7 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 7), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 7, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 5), an IC device (e.g., any of the IC structures 100A, 100B, 200A, 200B, 400G, described herein, or any combination of such IC devices), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 7, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 7 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 8 is a block diagram of an example electrical device 1800 that may include one or more IC structures in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 8 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 8, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.
Example 1 provides an IC structure, including a first layer including a first conductive element (e.g., a contact structure of a device); and a second layer over the first layer, the second layer including: a first insulator material (e.g., the low-k ILD), a second insulator material (e.g., a barrier layer) over the first insulator material, where the second insulator material is different from the first insulator material, and where the second insulator material includes fluorine, and a second conductive element (e.g., a via or metal line) connected to the first conductive element through the first insulator material and the second insulator material, where sidewalls of the second conductive element include fluorine.
Example 2 provides the IC structure of example 1, where: the second insulator material has one or more of a higher density and a higher dielectric constant than the first insulator material.
Example 3 provides the IC structure of any one of examples 1 or 2, where: the first insulator material has a first thickness; the second insulator material has a second thickness that is smaller than the first thickness; and the first thickness and the second thickness are dimensions in a plane substantially orthogonal to the first layer.
Example 4 provides the IC structure of example 3, where: the second thickness is in a range of 3-20 nanometers.
Example 5 provides the IC structure of any one of examples 1-4, where: the second insulator material includes fluorine.
Example 6 provides the IC structure of any one of examples 1-5, where: the first insulator material is a first dielectric material including silicon, oxygen, carbon, and hydrogen; and the second insulator material is a second dielectric material including silicon oxide.
Example 7 provides the IC structure of any one of examples 1-6, where: the sidewalls of the second conductive element include fluorine to a depth in a range of 5-25 nanometers, where the depth is a dimension in a plane parallel to the first layer.
Example 8 provides the IC structure of any one of examples 1-7, where: the second layer includes a third conductive element through the first insulator material and the second insulator material and adjacent to the second conductive element; and fluorine is present in a continuous portion of the first insulator material between the second conductive element and the third conductive element.
Example 9 provides the IC structure of any one of examples 1-7, where the sidewalls are first sidewalls, and where: the second layer includes a third conductive element through the first insulator material and the second insulator material and adjacent to the second conductive element. The first insulator material includes a portion between the second conductive element and the third conductive element, where the portion includes a first volume in contact with the second conductive element, a second volume in contact with the third conductive element, and a third volume between the first volume and the second volume, where a concentration of fluorine is lower in the third volume than in the first volume and the second volume.
Example 10 provides the IC structure of example 9, where: a concentration of carbon is higher in the third volume than in the first volume and the second volume.
Example 11 provides the IC structure of any one of examples 1-8, where: the second layer includes a third conductive element through the first insulator material and the second insulator material and adjacent to the second conductive element; and the first insulator material includes a portion between the second conductive element and the third conductive element, where the portion includes a first volume in contact with the second conductive element, a second volume in contact with the third conductive element, and a third volume between the first volume and the second volume, where a concentration of fluorine is about the same in the first volume, the second volume, and the third volume.
Example 12 provides the IC structure of any one of examples 1-11, where: the second conductive element includes a first portion in a same layer as the first insulator material, where the first portion has a first width, and a second portion in contact with the first portion and in a same layer as the second insulator material, where the second portion has a second width that is wider than the first width.
Example 13 provides an IC structure, including a first layer including a device contact structure; and a second layer over the first layer, the second layer including: a conductive interconnect coupled with the device contact structure, and one or more insulator materials surrounding the conductive interconnect, where the one or more insulator materials include fluorine at sidewalls of the conductive interconnect.
Example 14 provides the IC structure of example 13, where: the one or more insulator materials include: a first insulator material and a barrier layer over the first insulator material, where the barrier layer includes a second insulator material.
Example 15 provides the IC structure of any one of examples 13-14, where: a concentration of fluorine at the sidewalls of the conductive interconnect is in a range of 2-6%.
Example 16 provides the IC structure of any one of examples 13-15, where: fluorine is present in the first insulator material from the sidewalls of the conductive interconnect to a depth in a range of 5-25 nanometers, where the depth is a dimension in a plane parallel to the first layer.
Example 17 provides the IC structure of any one of examples 13-16, where the conductive interconnect is a first conductive interconnect, and where the IC structure further includes a second conductive interconnect in the second layer and adjacent to the first conductive interconnect, where fluorine is present in an entire volume between the first conductive interconnect and the second conductive interconnect.
Example 18 provides an integrated circuit (IC) structure, including a first layer including a first conductive element; a second layer over the first layer, the second layer including a second conductive element; and a third layer between the first layer and the second layer, the third layer including: an insulator material, a barrier layer over the insulator material, and a conductive interconnect through the insulator material and the barrier layer and between the first conductive element and the second conductive element, where the conductive interconnect has a first width in a first plane with the barrier layer and a second width in a second plane with the insulator material, and where the first width is smaller than the second width.
Example 19 provides the IC structure of example 18, where: the conductive interconnect has a third width in a third plane with the insulator material, where the third plane is closer to the first layer than the second plane, and where the third width is smaller than the second width.
Example 20 provides the IC structure of any one of examples 18-19, where: fluorine is present in sidewalls of the conductive interconnect and in the barrier layer.
Example 21 provides an IC structure according to any one of examples 1-20, where the IC structure includes or is a part of a central processing unit.
Example 22 provides an IC structure according to any one of examples 1-21, where the IC structure includes or is a part of a memory device.
Example 23 provides an IC structure according to any one of examples 1-22, where the IC structure includes or is a part of a logic circuit.
Example 24 provides an IC structure according to any one of examples 1-23, where the IC structure includes or is a part of input/output circuitry.
Example 25 provides an IC structure according to any one of examples 1-24, where the IC structure includes or is a part of a field programmable gate array transceiver.
Example 26 provides an IC structure according to any one of examples 1-25, where the IC structure includes or is a part of a field programmable gate array logic.
Example 27 provides an IC structure according to any one of examples 1-26, where the IC structure includes or is a part of a power delivery circuitry.
Example 28 provides an IC package that includes an IC die including an IC structure according to any one of examples 1-27; and a further IC component, coupled to the IC die.
Example 29 provides an IC package according to example 28 where the further IC component includes a package substrate.
Example 30 provides an IC package according to example 28, where the further IC component includes an interposer.
Example 31 provides an IC package according to example 28, where the further IC component includes a further IC die.
Example 32 provides a computing device that includes a carrier substrate and an IC structure coupled to the carrier substrate, where the IC structure is an IC structure according to any one of examples 1-27, or the IC structure is included in the IC package according to any one of examples 28-31.
Example 33 provides a computing device according to example 32, where the computing device is a wearable or handheld computing device.
Example 34 provides a computing device according to examples 32 or 33, where the computing device further includes one or more communication chips.
Example 35 provides a computing device according to any one of examples 32-34, where the computing device further includes an antenna.
Example 36 provides a computing device according to any one of examples 32-35, where the carrier substrate is a motherboard.
Example 37 provides a method of fabricating an IC structure, the method including providing a preliminary IC structure including a conductive contact structure surrounded by a first insulator material; providing an etch stop layer over the preliminary IC structure, the etch stop layer including a second insulator material; providing a third insulator material over the etch stop layer; providing a barrier layer over the third insulator material, the barrier layer including a fourth insulator material; providing a mask over the barrier layer, the mask including a first opening over the conductive contact structure; forming a second opening in the barrier layer and the third insulator material through the first opening in the mask; removing the mask with a dry etch process using fluorine radicals; removing the etch stop layer; providing a metal liner in the opening; and filling the opening with liner with a metal.
Example 38 provides the method of example 37, where: the conductive contact structure includes a metal contact structure for a transistor.
Example 39 provides the method of any one of examples 37 or 38, where: providing the third insulator material includes providing a layer of a dielectric material that includes silicon, oxygen and may include a methyl group (e.g., low-k dielectric such as SiCOH).
Example 40 provides the method of any one of examples 37-39, where: the barrier layer includes silicon oxide.
Example 41 provides the method of any one of examples 37-40, where: the fourth insulator material has one or more of a higher density and a higher dielectric constant than the third insulator material.
Example 42 provides the method of any one of examples 37-41, where: providing the mask includes providing a metallic hard mask over the barrier layer for a single or dual damascene process (e.g., via first or via last damascene processes), where the metallic hard mask includes one or more of an oxide, nitride, and carbide.
Example 43 provides the method of any one of examples 37-42, where: removing the mask includes removing the mask with the dry etch process without providing a carbon-based material over the conductive contact structure in the second opening prior to removing the mask.
Example 44 provides the method of any one of examples 37-43, where: removing the mask with the dry etch process includes fluorinating the third insulator material at sidewalls of the second opening (e.g., exposed to fluorine radicals).
Example 45 provides the method of any one of examples 37-44, where: removing the mask with the dry etch process includes fluorinating the fourth insulator material.
Example 46 provides the method of any one of examples 37-45, where: removing the mask with the dry etch process includes using a remote plasma to generate fluorine and hydrogen radicals.
Example 47 provides a method according to any one of examples 37-46, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a first layer including a first conductive element; and
a second layer over the first layer, the second layer including:
a first insulator material, a second insulator material over the first insulator material, wherein the second insulator material is different from the first insulator material, and wherein the second insulator material includes fluorine, and a second conductive element connected to the first conductive element through the first insulator material and the second insulator material, wherein sidewalls of the second conductive element include fluorine.

2. The IC structure of claim 1, wherein:
the second insulator material has one or more of a higher density and a higher dielectric constant than the first insulator material.

3. The IC structure of claim 1, wherein:
the first insulator material has a first thickness;
the second insulator material has a second thickness that is smaller than the first thickness; and
the first thickness and the second thickness are dimensions in a plane substantially orthogonal to the first layer.

4. The IC structure of claim 3, wherein:
the second thickness is in a range of 3-20 nanometers.

5. The IC structure of claim 1, wherein:
the second insulator material includes fluorine.

6. The IC structure of claim 1, wherein:
the first insulator material is a first dielectric material including silicon, oxygen, carbon, and hydrogen; and
the second insulator material is a second dielectric material including silicon oxide.

7. The IC structure of claim 1, wherein:
the sidewalls of the second conductive element include fluorine to a depth in a range of 5-25 nanometers, wherein the depth is a dimension in a plane parallel to the first layer.

8. The IC structure of claim 1, wherein:
the second layer includes a third conductive element through the first insulator material and the second insulator material and adjacent to the second conductive element; and
fluorine is present in a continuous portion of the first insulator material between the second conductive element and the third conductive element.

9. The IC structure of claim 1, wherein the sidewalls are first sidewalls, and wherein:
the second layer includes a third conductive element through the first insulator material and the second insulator material and adjacent to the second conductive element; and
the first insulator material includes a portion between the second conductive element and the third conductive element, wherein the portion includes:
a first volume in contact with the second conductive element, a second volume in contact with the third conductive element, and a third volume between the first volume and the second volume, wherein a concentration of fluorine is lower in the third volume than in the first volume and the second volume.

10. The IC structure of claim 9, wherein:
a concentration of carbon is higher in the third volume than in the first volume and the second volume.

11. The IC structure of claim 1, wherein:
the second layer includes a third conductive element through the first insulator material and the second insulator material and adjacent to the second conductive element; and
the first insulator material includes a portion between the second conductive element and the third conductive element, wherein the portion includes:
a first volume in contact with the second conductive element, a second volume in contact with the third conductive element, and a third volume between the first volume and the second volume, wherein a concentration of fluorine is about the same in the first volume, the second volume, and the third volume.

12. The IC structure of claim 1, wherein:
the second conductive element includes:
a first portion in a same layer as the first insulator material, wherein the first portion has a first width, and a second portion in contact with the first portion and in a same layer as the second insulator material, wherein the second portion has a second width that is wider than the first width.

13. An integrated circuit (IC) structure, comprising:
a first layer including a device contact structure; and
a second layer over the first layer, the second layer including:
a conductive interconnect coupled with the device contact structure, and one or more insulator materials surrounding the conductive interconnect, wherein the one or more insulator materials include fluorine at sidewalls of the conductive interconnect.

14. The IC structure of claim 13, wherein:
the one or more insulator materials include:
a first insulator material and a barrier layer over the first insulator material, wherein the barrier layer includes a second insulator material.

15. The IC structure of claim 13, wherein:
a concentration of fluorine at the sidewalls of the conductive interconnect is in a range of 2-6%.

16. The IC structure of claim 13, wherein:
fluorine is present in the first insulator material from the sidewalls of the conductive interconnect to a depth in a range of 5-25 nanometers, wherein the depth is a dimension in a plane parallel to the first layer.

17. The IC structure of claim 13, wherein the conductive interconnect is a first conductive interconnect, and wherein the IC structure further comprises:
a second conductive interconnect in the second layer and adjacent to the first conductive interconnect, wherein fluorine is present in an entire volume between the first conductive interconnect and the second conductive interconnect.

18. An integrated circuit (IC) structure, comprising:
a first layer including a first conductive element;
a second layer over the first layer, the second layer including a second conductive element; and
a third layer between the first layer and the second layer, the third layer including:
an insulator material, a barrier layer over the insulator material, and a conductive interconnect through the insulator material and the barrier layer and between the first conductive element and the second conductive element, wherein the conductive interconnect has a first width in a first plane with the barrier layer and a second width in a second plane with the insulator material, and wherein the first width is smaller than the second width.

19. The IC structure of claim 18, wherein:
the conductive interconnect has a third width in a third plane with the insulator material, wherein the third plane is closer to the first layer than the second plane, and wherein the third width is smaller than the second width.

20. The IC structure of claim 18, wherein:
fluorine is present in sidewalls of the conductive interconnect and in the barrier layer.
